(19) United States
(12) Patent Application Publication
(10) Pub. No.: US 2026/0292965 A1
(43) Pub. Date: Sep. 24, 2026

(54) WIRING SUBSTRATE

(71) Applicant: NITERRA CO., LTD., Nagoya-shi (JP)

(72) Inventors: Fumio SHIRAKI, Nagoya-shi (JP); Yoshitaka IWAHARA, Nagoya-shi (JP); Chu KANEMITSU, Nagoya-shi (JP)

(21) Appl. No.: 19/543,528

(22) Filed: Feb. 18, 2026

(30) Foreign Application Priority Data
Mar. 24, 2025 (JP) 2025-048049

(51) Int. Cl. H05K 1/02; H05K 1/03

(52) U.S. Cl. CPC H05K 1/0201; H05K 1/0306; H05K 2201/066

(57) ABSTRACT

A technique for suppressing generation of a crack in a joint portion of a wiring substrate is provided. The wiring substrate includes: a ceramic substrate formed of a ceramic material and having wiring; a metallic member which includes a base member containing a first metal and a protection film containing a second metal different from the first metal and covering a surface of the base member; and a joining layer which contains the first metal disposed between the ceramic substrate and the metallic member, and joining the ceramic substrate and the metallic member to each other. In a region between the joining layer and the base member, the protection film is broken and discontinuous, and the joining layer and the base member are directly joined to each other.

### BACKGROUND OF THE INVENTION

### Field of the Invention

The present invention relates to a wiring substrate.

### Description of the Related Art

Heretofore, there has been known a wiring substrate in which a substrate having wiring and a base member containing a metal are joined together (see, for example, JP2018-111883A).

However, the prior art technique as disclosed in JP2018-111883A still has room for improvement in terms of suppression of generation of a crack in a joint portion of the wiring substrate.

### SUMMARY OF THE INVENTION

An object of the present invention is to provide a technique for suppressing generation of a crack in a joint portion of a wiring substrate.

The present invention has been accomplished so as to solve at least partially the above-described problem. The present invention can be realized as the following aspect.

(1) According to one aspect of the present invention, a wiring substrate is provided. The wiring substrate includes: a ceramic substrate formed of a ceramic material and having wiring; a metallic member which includes a base member containing a first metal and a protection film containing a second metal different from the first metal and covering a surface of the base member; and a joining layer which contains the first metal, disposed between the ceramic substrate and the metallic member, and joining the ceramic substrate and the metallic member to each other. In a region between the joining layer and the base member, the protection film is broken and discontinuous, and the joining layer and the base member are directly joined to each other.

According to this configuration, the region where the joining layer and the base member are directly joined to each other is present at least partially between the joining layer and the base member. In the region where the joining layer and the base member are joined directly to each other, the first metal contained in the joining layer and the first metal contained in the base member are fused together. Therefore, the joining layer and the base member are joined strongly in the region where the joining layer and the base member are joined directly to each other. In the region where the joining layer and the base member are joined directly to each other, even when the temperature of the wiring substrate changes, it is possible to suppress generation of a crack due to the difference in coefficient of thermal expansion between the material of the joining layer and the material of the protection film and the difference in coefficient of thermal expansion between the material of the base member and the material of the protection film. In addition, in the entire surface region of the metallic member, excluding the surface region where the metallic member is joined to the ceramic substrate, the base member is covered by the protection film containing the second metal. Therefore, the base member can be protected.

(2) In the wiring substrate of the above-described aspect, the second metal may be interspersed in the region. According to this configuration, the second metal interspersed in the region is fixed as a result of being sandwiched between the joining layer and the base member. A portion of the fixed second metal is connected and unified with the second metal contained in the protection film covering the surface of the base member. Therefore, the protection film covering the surface of the base member becomes less likely to peel off.

(3) In the wiring substrate of the above-described aspect, the metallic member may be a heat releasing member which releases heat generated in the ceramic substrate to the outside. According to this configuration, even when the temperature of the ceramic substrate increases, the metallic member releases the heat generated in the ceramic substrate to the outside. Therefore, the heat dissipation performance of the wiring substrate is enhanced, and temperature rise of the wiring substrate is suppressed, whereby thermal expansion of the wiring substrate is suppressed. As a result, it is possible to suppress generation of a crack due to the difference in coefficient of thermal expansion between the respective members of the wiring substrate.

(4) In the wiring substrate of the above-described aspect, the first metal may be silver. According to this configuration, in the region where the joining layer and the base member are joined directly to each other, the silver contained in the joining layer and the silver contained in the base member are fused together. Therefore, in the region where the joining layer and the base member are joined directly to each other, even when the temperature of the wiring substrate changes, the effect of suppressing generation of a crack due to the difference in coefficient of thermal expansion between the material of the joining layer and the material of the protection film and the difference in coefficient of thermal expansion between the material of the base member and the material of the protection film is enhanced.

(5) In the wiring substrate of the above-described aspect, the second metal may be nickel, and the protection film on the surface of the base member may have a thickness of 0.1 micrometers or more and 1.0 micrometer or less. No particular limitation is imposed on the thickness of the protection film, so long as the joining layer and the base member can be joined to each other, whereby they are unified. The thickness of the protection film is preferably 0.3 micrometers or more and 0.8 micrometers or less, more preferably 0.5 micrometers or more and 0.7 micrometers or less. According to this configuration, the protection film containing nickel covers the surface of the base member in the entire surface region of the metallic member, excluding the surface region where the metallic member is joined to the ceramic substrate. Therefore, the effect of protecting the base member is enhanced.

The present invention can be realized in various aspects. For example, the present invention can be realized, for example, as a product which includes a wiring substrate, a method for manufacturing a wiring substrate, and a method for manufacturing a product which includes a wiring substrate.

### BRIEF DESCRIPTION OF THE DRAWINGS

FIG. 1 is an explanatory view schematically showing a wiring substrate 10 of a first embodiment;

FIG. 2 is an explanatory view showing a cross section of the wiring substrate 10 along an XZ plane;

FIG. 3 is an explanatory view showing, on an enlarged scale, a joint portion between a joining layer 40 and a metallic member 80;

FIG. 4 is a process chart showing a method for manufacturing the wiring substrate 10;

FIGS. 5(A) to 5(C) are explanatory views schematically showing a process of joining a ceramic substrate 20 and the metallic member 80; and

FIG. 6 is an explanatory view showing a cross section, along the XZ plane, of a wiring substrate 11 of a comparative example.

### DESCRIPTION OF THE PREFERRED EMBODIMENT

### First embodiment

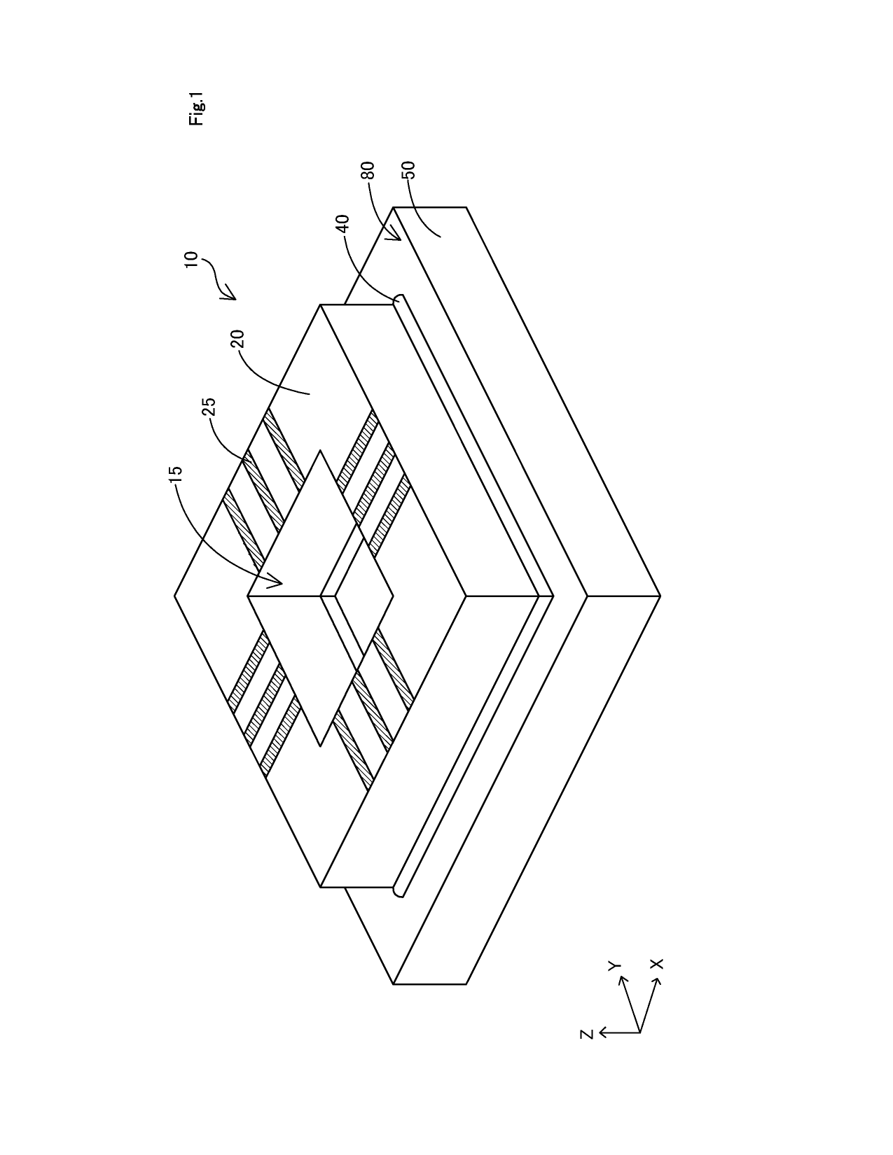

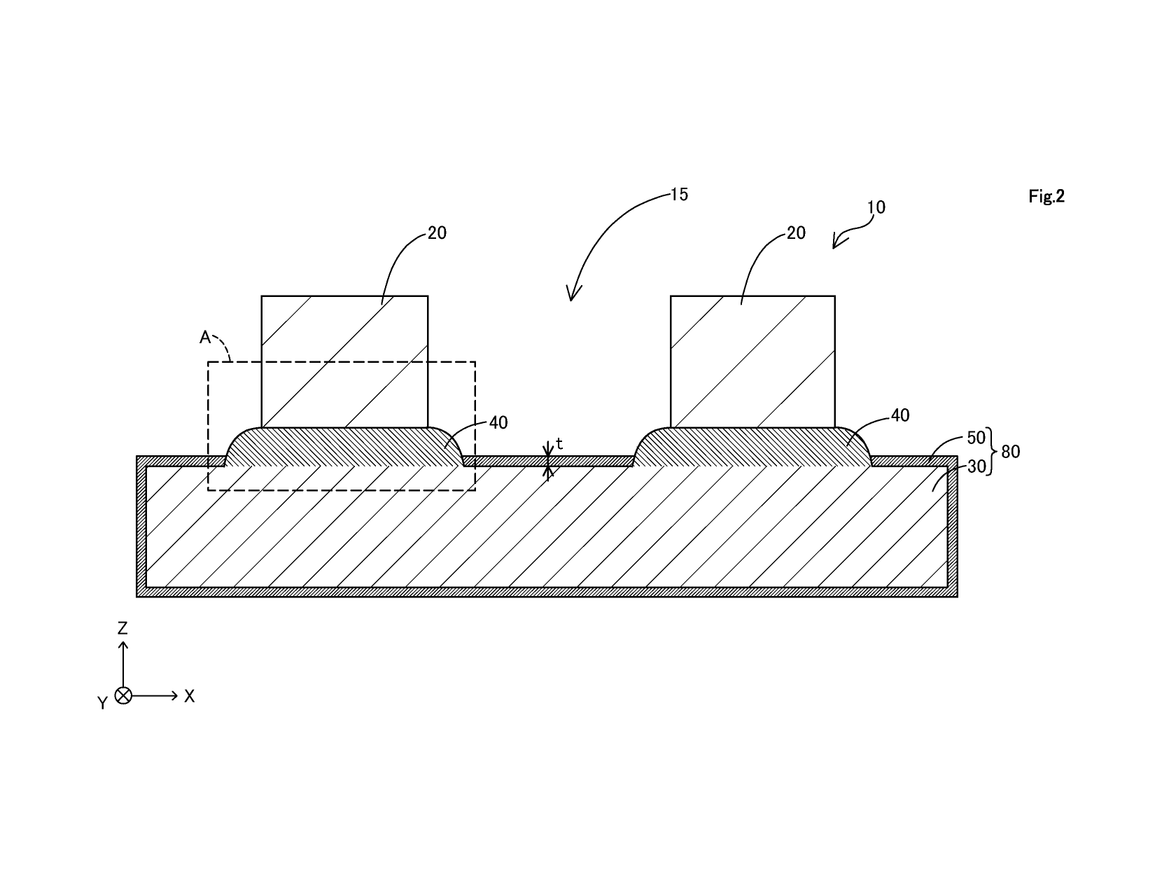

FIG. 1 is an explanatory view schematically showing a wiring substrate 10 of a first embodiment. FIG. 2 is an explanatory view showing a cross section of the wiring substrate 10 along an XZ plane. A region between a joining layer 40 and a base member 30 in a cross section including a ceramic substrate 20, the joining layer 40, and a metallic member 80 will be described with reference to FIG. 2. In FIGS. 1, 2, 3, and 6, an X axis, a Y axis, and a Z axis, which are orthogonal to one another, are shown so as to specify the respective directions. The X axis, the Y axis, and the Z axis in these drawings represent the same respective directions. In the specification of the present application, the Z axis shows a vertical direction, and the X axis and the Y axis show horizontal directions. Also, the vertical direction and the horizontal directions mentioned above are specified for convenience of description. Notably, respective portions in the drawings schematically represent their arrangements and do not accurately represent the ratios of dimensions of the respective portions. In addition, in the following description, as to a member which extends along an XY plane, its surface on a +Z direction side (the upper side in the vertical direction) will be also referred to as the "front surface," and its surface on a -Z direction side (the lower side in the vertical direction) will be also referred to as the "back surface."

The wiring substrate 10 of the first embodiment includes the ceramic substrate 20, the metallic member 80, and the joining layer 40. As shown in FIGS. 1 and 2, in the wiring substrate 10 of the first embodiment, the ceramic substrate 20 is stacked on the metallic member 80 with the joining layer 40 intervening therebetween. In the wiring substrate 10, an electronic component (not shown) is disposed in a recess 15 surrounded by the ceramic substrate 20.

The ceramic substrate 20 is formed of a ceramic material containing, for example, alumina as a main component, and has wiring 25. A portion of the wiring 25 is exposed to the outside and is electrically connected to the electronic component. The ceramic substrate 20 is joined at its back surface to the joining layer 40.

The metallic member 80 includes the base member 30 which contains silver and diamond, and a protection film 50 which contains nickel and covers the surface of the base member 30. The metallic member 80 is joined to the joining layer 40. The metallic member 80 has an approximately rectangular parallelepiped shape.

The base member 30 is mainly formed of a silver-diamond composite material. Notably, the base member 30 may be mainly formed of a copper-diamond composite material. Also, the base member 30 may be mainly formed of tin. Heat generated in the ceramic substrate 20 is transferred to the base member 30 through the joining layer 40, and the base member 30 releases the heat to the outside through the protection film 50. The metallic member 80 including the base member 30 and the protection film 50 is a heat releasing member which releases the heat generated in the ceramic substrate 20 to the outside. Even when the temperature of the ceramic substrate 20 increases, the metallic member 80 releases the heat generated in the ceramic substrate 20 to the outside. Therefore, the heat dissipation performance of the wiring substrate 10 is enhanced, whereby temperature rise of the wiring substrate 10 is suppressed, and thus thermal expansion of the wiring substrate 10 is suppressed. As a result, it is possible to suppress generation of a crack due to the difference in coefficient of thermal expansion between the respective members of the wiring substrate 10. Notably, the metallic member 80 is not required to be a heat releasing member.

The protection film 50 is formed on the surface of the base member 30 in the entire surface region of the metallic member 80, excluding a surface region where the metallic member 80 is joined to the ceramic substrate 20. The protection film 50 is mainly formed of nickel and prevents oxidation of the base member 30. The protection film 50 may be mainly formed of gold, copper, or titanium. The protection film 50 is not required to be a film which prevents oxidation of the base member 30. For example, the protection film 50 may be a film for protecting the base member 30 from impacts from the outside. No particular limitation is imposed on the thickness t of the protection film 50, so long as the protection film 50 becomes broken and discontinuous when the ceramic substrate 20 and the metallic member 80 are joined together. Over the entire region where the protection film 50 is formed, the thickness t of the protection film 50 is preferably 0.1 micrometers or more and 1.0 micrometer or less, more preferably 0.3 micrometers or more and 0.8 micrometers or less, further preferably 0.5 micrometers or more and 0.7 micrometers or less. Since the protection film 50 containing nickel covers the surface of the base member 30 in the entire surface region of the metallic member 80, excluding the surface region where the metallic member 80 is joined to the ceramic substrate 20, the base member 30 can be protected.

The joining layer 40 is disposed between the ceramic substrate 20 and the metallic member 80. The joining layer 40 joins the ceramic substrate 20 and the metallic member 80. The joining layer 40 and the ceramic substrate 20 are joined by a silver brazing filler metal containing silver and copper. Similarly, the joining layer 40 and the metallic member 80 are joined by a silver brazing filler metal containing silver and copper. The joining may be performed by using a solder containing silver. Also, the base member 30 may be formed mainly of a copper-diamond composite material, and the joining may be performed by using a silver brazing filler metal containing silver and copper. In the case where the base member 30 is mainly formed of tin, the joining may be performed by using a solder containing tin.

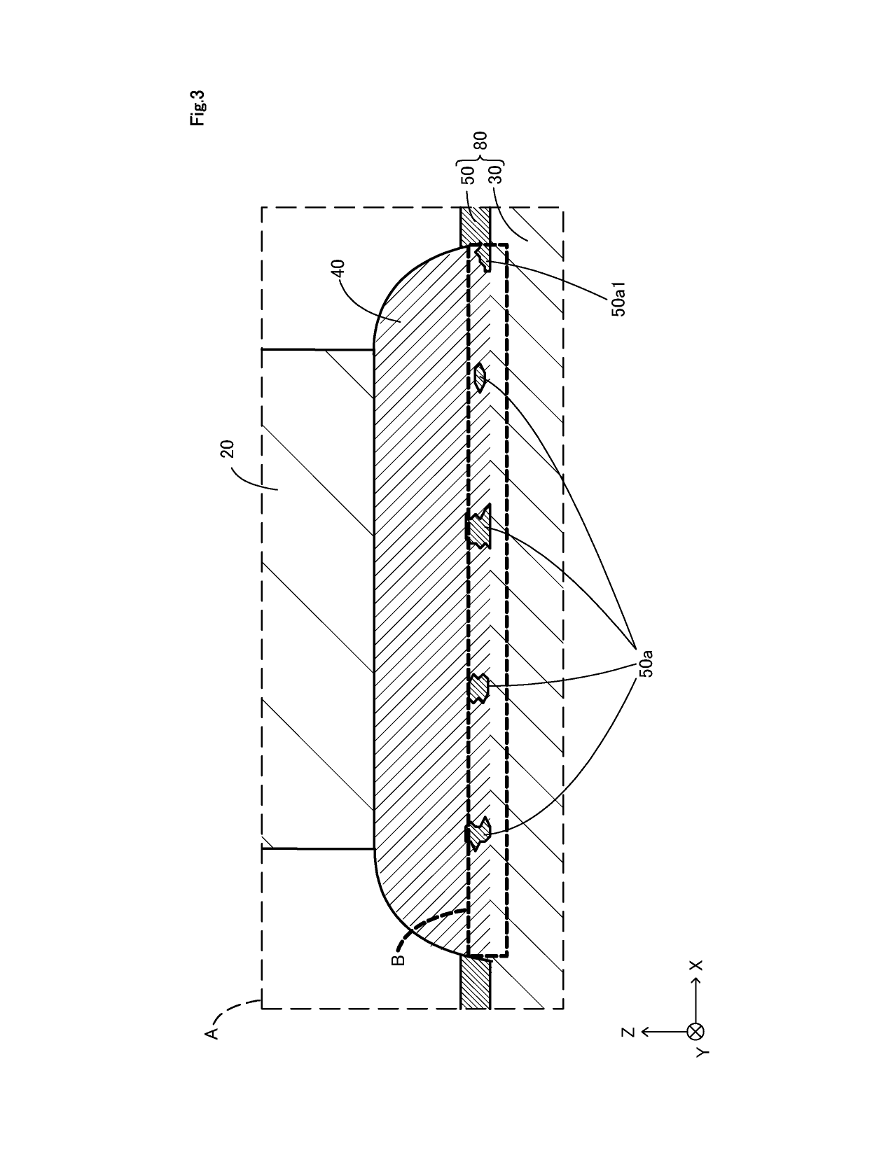

FIG. 3 is an explanatory view showing, on an enlarged scale, a joint portion between the joining layer 40 and the metallic member 80. Specifically, FIG. 3 is an explanatory view showing, on an enlarged scale, a region A in FIG. 2 surrounded by a broken line. The feature of the wiring substrate 10 of the first embodiment will be described. In a cross section including the ceramic substrate 20, the joining layer 40, and the metallic member 80, the protection film 50 is broken and discontinuous at least in a portion (region B) of the interface between the joining layer 40 and the base member 30. In the region B where the protection film 50 is broken and discontinuous, the joining layer 40 containing silver and the base member 30 containing silver are joined directly to each other, and the silver contained in the joining layer 40 and the silver contained in the base member 30 are fused together. Therefore, in the region B where the joining layer 40 and the base member 30 are joined directly to each other, the joining layer 40 and the base member 30 are joined strongly. In the region B, even when the temperature of the wiring substrate 10 changes, it is possible to suppress generation of a crack due to the difference in coefficient of thermal expansion between the material of the joining layer 40 and the material of the protection film 50 and the difference in coefficient of thermal expansion between the material of the base member 30 and the material of the protection film 50. In addition, in the entire surface region of the metallic member 80, excluding the surface region where the metallic member 80 is joined to the ceramic substrate 20, the base member 30 is covered by the protection film 50 containing nickel. Therefore, the base member 30 can be protected. Notably, the metal contained in the joining layer 40 and the base member 30 and unified may be other than silver; for example, the metal may be copper or tin.

In the region B, nickel 50a is interspersed. The nickel 50a sandwiched and interspersed between the joining layer 40 and the base member 30 is fixed as a result of being sandwiched between the joining layer 40 and the base member 30. A portion 50a1 of the fixed nickel 50a is connected and unified with the nickel contained in the protection film 50 covering the surface of the base member 30. Therefore, the protection film 50 covering the surface of the base member 30 becomes less likely to peel off. Notably, the metal contained in the protection film and interspersed in the region B where the joining layer 40 and the base member 30 are joined directly to each other may be other than nickel. For example, the metal may be gold, copper, or titanium.

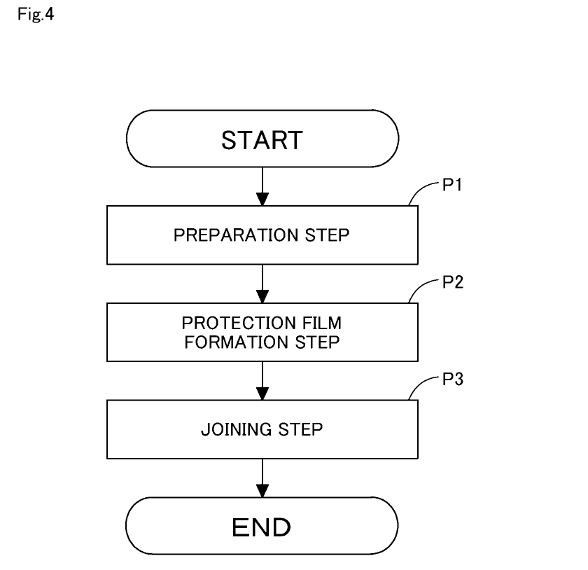

FIG. 4 is a process chart showing a method for manufacturing the wiring substrate 10. The method for manufacturing the wiring substrate 10 will be described with reference to FIG. 4. The method for manufacturing the wiring substrate 10 includes a preparation step (P1), a protection film formation step (P2), and a joining step (P3), which are performed in this order.

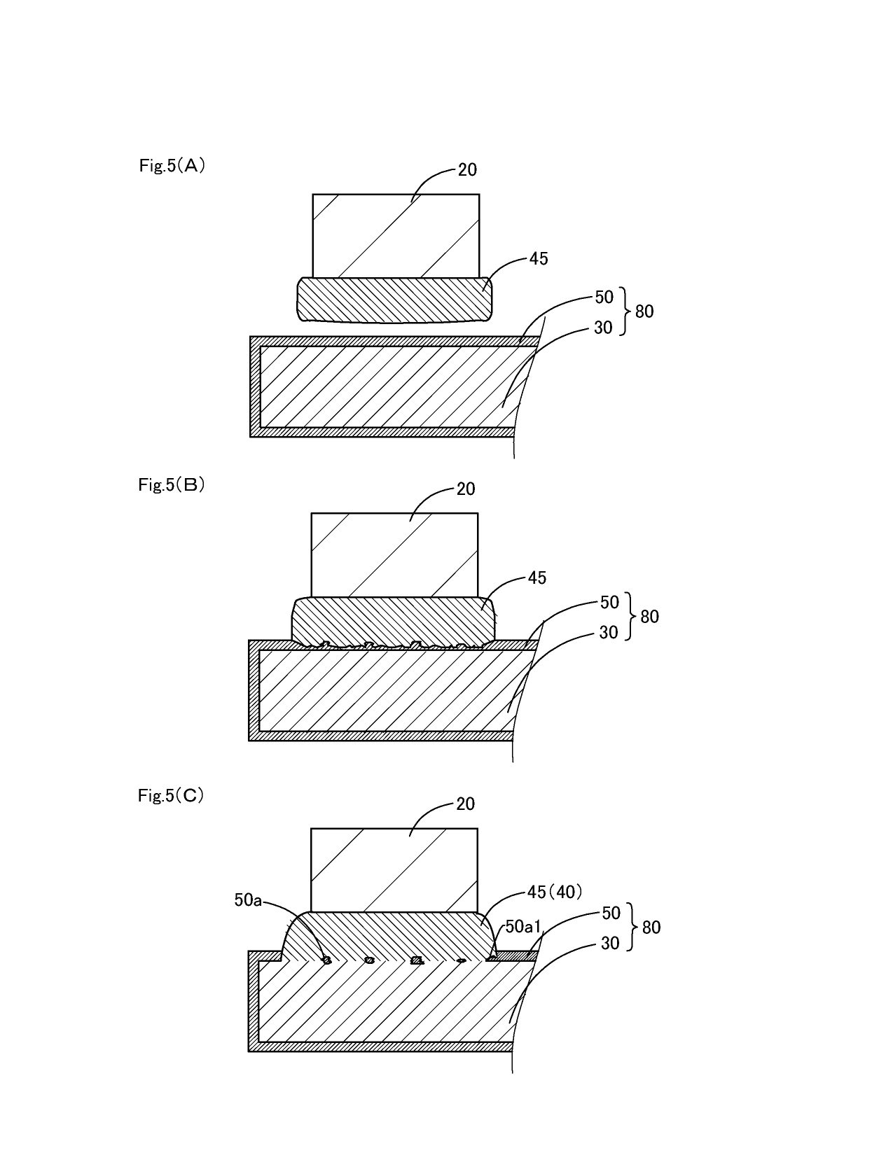

In the preparation step (P1), the ceramic substrate 20, a silver brazing filler metal 45 (FIGS. 5(A) to 5(C)), and the base member 30 are prepared. The ceramic substrate 20 is formed of a ceramic material and has the wiring 25. The silver brazing filler metal 45 contains silver and copper. The base member 30 is mainly formed of a silver-diamond composite material.

In the protection film formation step (P2), the entire surface of the base member 30 is covered with the nickel-containing protection film 50 by using an electroplating method. The entire surface of the base member 30 may be covered with the nickel-containing protection film 50 by any of other methods, without using the electroplating method. The thickness of the protection film 50 is adjusted such that, over the entire surface of the protection film 50, the thickness becomes 0.1 micrometers or more and 1.0 micrometer or less. Notably, no particular limitation is imposed on the thickness of the protection film 50, so long as the joining layer 40 and the base member 30 can be joined and fused with each other.

In the joining step (P3), first, the heated silver brazing filler metal 45 is brazed to the back surface of the ceramic substrate 20. Subsequently, the back surface of the ceramic substrate 20 and the front surface of the metallic member 80 are brazed and joined by using the silver brazing filler metal 45. Notably, the method for manufacturing the wiring substrate 10 is not limited to the above-described manufacturing method. For example, the ceramic substrate 20 and the metallic member 80 may be joined by means of soldering.

FIGS. 5(A) to 5(C) are explanatory views schematically showing a process of joining the ceramic substrate 20 and the metallic member 80. The state of a region where the back surface of the ceramic substrate 20 and the front surface of the metallic member 80 are joined as a result of the brazing in the joining step (P3) performed by using the heated silver brazing filler metal 45 will be described in detail with reference to FIGS. 5(A) to 5(C).

FIG. 5(A) shows a state before the ceramic substrate 20 and the metallic member 80 are joined. The entire surface of the base member 30 of the metallic member 80 is covered by the protection film 50.

FIG. 5(B) is a state in which the ceramic substrate 20 and the metallic member 80 have been brought into contact with each other. Because of heat of the heated silver brazing filler metal 45, the protection film 50 having come into contact with the silver brazing filler metal 45 starts to diffuse and become broken and discontinuous.

FIG. 5(C) shows a state in which the ceramic substrate 20 and the metallic member 80 have been joined to each other. The protection film 50 becomes broken and discontinuous, and the silver contained in the silver brazing filler metal 45 in the joining layer 40 and the silver contained in the base member 30 are joined directly and fused with each other. In the region where the joining layer 40 and the base member 30 are joined directly to each other, the nickel 50a contained in the broken protection film 50 is interspersed. The nickel 50a sandwiched and interspersed between the joining layer 40 and the base member 30 is fixed as a result of being sandwiched between the joining layer 40 and the base member 30. The portion 50a1 of the fixed nickel 50a is connected and unified with the nickel contained in the protection film 50.

### Comparative Example

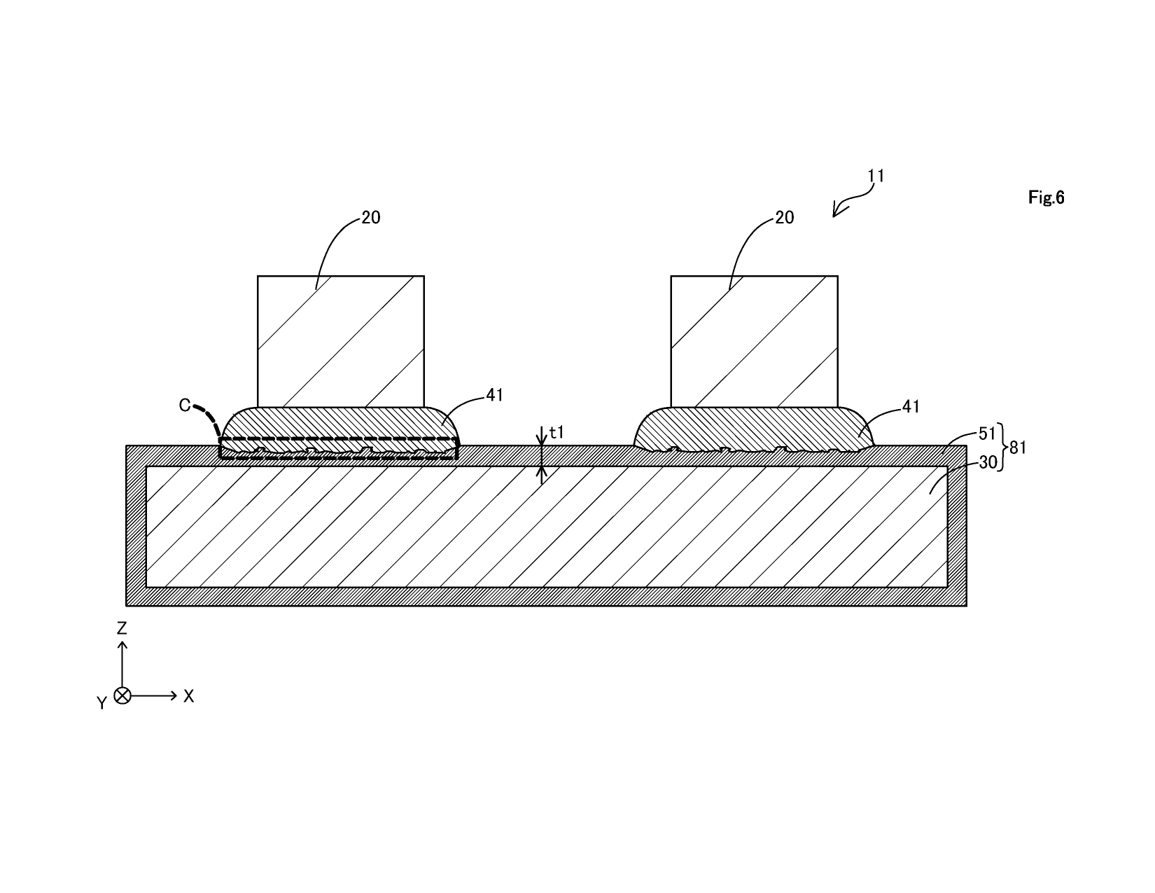

FIG. 6 is an explanatory view showing a cross section, along the XZ plane, of a wiring substrate 11 of a comparative example. The difference of the wiring substrate 11 of the comparative example will be described. The wiring substrate 11 differs from the wiring substrate 10 in that a protection film 51 in the substrate 11 has a thickness t1, which differs from the thickness t of the protection film 50 in the wiring substrate 10, and in that, in the cross section containing the ceramic substrate 20, a joining layer 41, and a metallic member 81, the protection film 51 between the joining layer 41 and the base member 30 is not broken.

In the region where the ceramic substrate 20 and the metallic member 81 are not joined, the protection film 51 in the wiring substrate 11 is formed such that its thickness t1 falls within a range of 2.0 micrometers to 3.0 micrometers (inclusive). Before the ceramic substrate 20 and the metallic member 81 are joined, the protection film 51 was formed such that its thickness t1 fell within the range of 2.0 micrometers to 3.0 micrometers (inclusive) over the entire surface of the metallic member 81. In a region C where the ceramic substrate 20 and the metallic member 81 are joined, the protection film 51 does not become broken and discontinuous. The reason why the protection film 51 does not become broken and discontinuous in the region C where the ceramic substrate 20 and the metallic member 81 are joined is that, when the silver brazing filler metal in the joining layer 41 was heated for brazing with the protection film 51, since the thickness t1 of the protection film 51 was excessively large, the protection film 51 did not diffuse to such an extent that protection film 51 became broken and discontinuous.

In the configuration of the comparative example, a region where the protection film 51 containing nickel is broken and discontinuous is not present between the joining layer 41 and the base member 30. Therefore, the silver contained in the joining layer 41 and the silver contained in the base member 30 are not joined directly and are not fused together. In the wiring substrate 11 of the comparative example, when the temperature of the wiring substrate 11 changes, generation of a crack is likely to occur due to the difference in coefficient of thermal expansion between the material of the joining layer 41 and the material of the protection film 51 and the difference in coefficient of thermal expansion between the material of the base member 30 and the material of the protection film 51.

### Advantageous effect of the first embodiment

According to the configuration of the first embodiment as described above, the wiring substrate 10 includes the ceramic substrate 20 formed of a ceramic material and having the wiring 25; the metallic member 80 including the base member 30 containing silver and the protection film which contains nickel and covers the surface of the base member 30; and the joining layer 40 which contains silver, is disposed between the ceramic substrate 20 and the metallic member 80, and joins the ceramic substrate 20 and the metallic member 80. In a cross section including the ceramic substrate 20, the joining layer 40, and the metallic member 80, the region B where the protection film 50 is broken and discontinuous and the joining layer 40 and the base member 30 are directly joined to each other is present at least partially between the joining layer 40 and the base member 30. Therefore, in the region B where the joining layer 40 and the base member 30 are joined directly to each other, the silver contained in the joining layer 40 and the silver contained in the base member 30 are fused together, and thus, the joining layer 40 and the base member 30 are joined strongly. In the region B, even when the temperature of the wiring substrate 10 changes, it is possible to suppress generation of a crack due to the difference in coefficient of thermal expansion between the material of the joining layer 40 and the material of the protection film 50 and the difference in coefficient of thermal expansion between the material of the base member 30 and the material of the protection film 50. In addition, in the entire surface region of the metallic member 80, excluding the surface region where the metallic member 80 is joined to the ceramic substrate 20, the base member 30 is covered by the protection film 50 containing nickel. Therefore, the base member 30 can be protected.

In addition, nickel 50a may be interspersed in the region B where the joining layer 40 and the base member 30 are joined directly to each other. Therefore, the nickel 50a sandwiched and interspersed between the joining layer 40 and the base member 30 is fixed as a result of being sandwiched between the joining layer 40 and the base member 30. The portion 50a1 of the fixed nickel 50a is connected and unified with the nickel contained in the protection film 50 covering the surface of the base member 30. Therefore, the protection film 50 covering the surface of the base member 30 becomes less likely to peel off.

In addition, the metallic member 80 may be a heat releasing member which releases the heat generated in the ceramic substrate 20 to the outside. Therefore, even when the temperature of the ceramic substrate 20 increases, the metallic member 80 releases the heat generated in the ceramic substrate 20 to the outside. Therefore, the heat dissipation performance of the wiring substrate 10 is enhanced, whereby temperature rise of the wiring substrate 10 is suppressed, and thus thermal expansion of the wiring substrate 10 is suppressed. As a result, it is possible to suppress generation of a crack due to the difference in coefficient of thermal expansion between the respective members of the wiring substrate 10.

In addition, the metal contained in the protection film 50 may be nickel, and the thickness of the protection film 50 on the surface of the base member 30 may be 0.1 micrometers or more and 1.0 micrometer or less. No particular limitation is imposed on the thickness of the protection film 50, so long as the joining layer and the base member can be joined to each other, whereby they are unified. Since the surface of the base member 30 is covered with the protection film 50 containing nickel in the entire surface region of the metallic member 80, excluding the surface region where the metallic member 80 is joined to the ceramic substrate 20, the base member 30 can be protected.

Notably, the metal contained in the joining layer 40 and the base member 30 and unified may be other than silver; for example, copper or tin. In addition, the metal contained in the protection film may be other than nickel; for example, gold, copper or titanium.

### Modifications of the present embodiment

The present invention is not limited to the above-described embodiment and can be practiced in various forms without departing from the gist of the invention. For example, the following modifications are possible.

### Modification 1

In the above-described wiring substrate 10 of the first embodiment, nickel 50a is interspersed between the joining layer 40 and the base member 30. However, the greater part of the protection film 50 may remain between the joining layer 40 and the base member 30. In such a case, only a portion of the protection film 50 becomes broken and discontinuous , and, in a region where the portion of the protection film 50 becomes broken and discontinuous, the joining layer 40 and the base member 30 come into directly contact with each other, and the silver contained in the joining layer 40 and the silver contained in the base member 30 are fused together, whereby the joining layer 40 and the base member 30 are directly connected to each other.

### Modification 2

In the above-described wiring substrate 10 of the first embodiment, nickel 50a is interspersed between the joining layer 40 and the base member 30. However, nickel 50a is not required to be present between the joining layer 40 and the base member 30. In addition, a metal other than nickel may be interspersed between the joining layer 40 and the base member 30, and a substance other than metals may be interspersed between the joining layer 40 and the base member 30.

Although the present invention has been described on the basis of its embodiment and modifications, the above-described embodiment is provided so as to facilitate the understanding of the present invention and does not limit the present invention. The present invention can be changed or improved without departing from the purpose and the scope of the claims, and encompasses equivalents thereof. Also, the technical feature(s) may be eliminated unless the present specification mentions that the technical feature(s) is essential.

### Application example 1

A wiring substrate comprising:

a ceramic substrate formed of a ceramic material and having wiring;

a metallic member which includes a base member containing a first metal and a protection film containing a second metal different from the first metal and covering a surface of the base member; and

a joining layer which contains the first metal, disposed between the ceramic substrate and the metallic member, and joining the ceramic substrate and the metallic member to each other,

wherein, in a region between the joining layer and the base member, the protection film is broken and discontinuous, and the joining layer and the base member are directly joined to each other.

### Application example 2

The wiring substrate described in the application example 1, wherein the second metal is interspersed in the region.

### Application example 3

The wiring substrate described in the application example 1 or the application example 2, wherein the metallic member is a heat releasing member which releases heat generated in the ceramic substrate to an outside.

### Application example 4

The wiring substrate described in the application example 1 or the application example 2, wherein the first metal is silver.

### Application example 5

The wiring substrate described in the application example 4, wherein the second metal is nickel, and the protection film on the surface of the base member has a thickness of 0.1 micrometers or more and 1.0 micrometer or less.

What is claimed is:

1. A wiring substrate comprising:
a ceramic substrate formed of a ceramic material and having wiring;
a metallic member which includes a base member containing a first metal and a protection film containing a second metal different from the first metal and covering a surface of the base member; and
a joining layer which contains the first metal disposed between the ceramic substrate and the metallic member, and joining the ceramic substrate and the metallic member to each other,
wherein, in a region between the joining layer and the base member, the protection film is broken and discontinuous, and the joining layer and the base member are directly joined to each other.

2. The wiring substrate according to claim 1, wherein the second metal is interspersed in the region.

3. The wiring substrate according to claim 1, wherein the metallic member is a heat releasing member which releases heat generated in the ceramic substrate to an outside.

4. The wiring substrate according to claim 1, wherein the first metal is silver.

5. The wiring substrate according to claim 4, wherein the second metal is nickel, and the protection film on the surface of the base member has a thickness of 0.1 micrometers or more and 1.0 micrometer or less.

6. The wiring substrate according to claim 2, wherein the metallic member is a heat releasing member which releases heat generated in the ceramic substrate to an outside.

7. The wiring substrate according to claim 2, wherein the first metal is silver.

8. The wiring substrate according to claim 7, wherein the second metal is nickel, and the protection film on the surface of the base member has a thickness of 0.1 micrometers or more and 1.0 micrometer or less.
